(19) United States
(12) Patent Application Publication
(10) Pub. No.: US 2025/0275221 A1
(43) Pub. Date: Aug. 28, 2025

(54) AIR-GAP IN TRENCH FIELD PLATE POWER MOSFET FOR REDUCED POWER LOSS PERFORMANCE

(71) Applicant: STMicroelectronics International N.V., Geneva (CH)

(72) Inventors: Chia-Liang LIAO, Singapore (SG); Voon Cheng NGWAN, Singapore (SG); Vincenzo ENEA, Siracusa (IT)

(73) Assignee: STMicroelectronics International N.V., Geneva (CH)

(21) Appl. No.: 18/590,785

(22) Filed: Feb. 28, 2024

(51) Int. Cl. H01L 29/49; H01L 21/764; H01L 21/768; H01L 29/40

(52) U.S. Cl. CPC H10D 64/679; H01L 21/764; H01L 21/76816; H10D 64/117

(57) ABSTRACT

A power MOSFET device including at least one air gap between a buried polysilicon source and a sidewall of a recessed substrate. The device includes a plurality of insulating layers on the substrate and delimiting the air gap.

### BACKGROUND

### Technical Field

A power Metal Oxide Semiconductor Field Effect Transistor (MOSFET) device including at least one air gap spaced from a source polysilicon region in a recessed substrate.

### Description of the Related Art

During operation of a MOSFET device, there is an on-resistance or Ron value between a drain of the device and a gate source of the device. The Ron value contributes to the power consumption of the device. Thus, a lower Ron value results in a lower loss of power of the device.

A Trench Field Plate Power MOSFET device is a low voltage power MOSFET device with a lower Ron value. A dielectric material of the device contributes to the performance of the device and gate capacitance. The dielectric material often used in the device is silicon dioxide having a dielectric constant of k or kappa equal to 3.9.

When silicon dioxide is replaced with an insulator material having a lower dielectric constant the on-state resistance contributed by a silicon component (Rsil) is lowered, measured by a unit denoted by mΩ*mm².

$${R}_{on} ∝ \frac{0.72}{{γ}_{FP}} SiLimit ,$$

$${γ}_{FP} = \frac{{t}_{FP}}{2 {W}_{i} + {W}_{n}} = \frac{1}{2 \sqrt{\frac{2}{3}} \frac{{ε}_{i}}{{ε}_{s}} + \frac{{W}_{n}}{{t}_{FP}}} ,$$

wherein γ_{FP} is the cell aspect ratio of the field plate, εₛ and εᵢ are dielectric constants of the semiconductor and insulator, respectively, t_{FP} is field plate thickness, Wₙ is the n-column width, and Wᵢ is insulator width.

The lowest possible dielectric constant is k=1 from air. Packets of air are formed during back end of line copper interconnects to form packets of air to lower the effective capacitance to reduce signal propagation RC (Resistance-Capacitance) delay.

### BRIEF SUMMARY

A power MOSFET device including at least one air gap and a buried polysilicon source in an insulating layer. The air gap being between the buried polysilicon source and a recess sidewall in a substrate.

The present disclosure is directed to a device that includes a power MOSFET that includes a substrate having a recess in a first surface of the substrate, the first surface extending in a first direction, the recess having sidewalls extending in a second direction transverse the first direction, the recess including a second surface extending in the first direction between the sidewalls. The device includes an insulating layer on the first surface of the substrate and in the recess, a first polysilicon region in the insulating layer, the first polysilicon region extending in the second direction for a first dimension, and an air gap in the insulating layer between the first polysilicon region and the substrate, the air gap extending in the second direction for a second dimension being less than the first dimension.

An air gap in the field plate region, replaces silicon dioxide with air, achieving a better Rsil performance. The air gap (k=1) in a field plate power MOSFET device contributes to overcome the Si-limit.

### BRIEF DESCRIPTION OF THE SEVERAL VIEWS OF THE DRAWINGS

In the drawings, identical reference numbers identify similar features or elements. The size and relative positions of features in the drawings are not necessarily drawn to scale, however the relationships between features are representative of relationships in a final product.

FIG. 1 is a power MOSFET device according to an embodiment.

FIG. 2 is a power MOSFET device including a nitride layer, according to another embodiment.

FIGS. 3A-3R are steps of a method of manufacturing the device of FIG. 2.

FIGS. 4A-4F are steps of a method of manufacturing the device of FIG. 1.

### DETAILED DESCRIPTION

Bottom and top are used for orientation and simplicity in understanding the Figures. Bottom and top are relative to the Figures as presented but may be reversed as positioned in a final product.

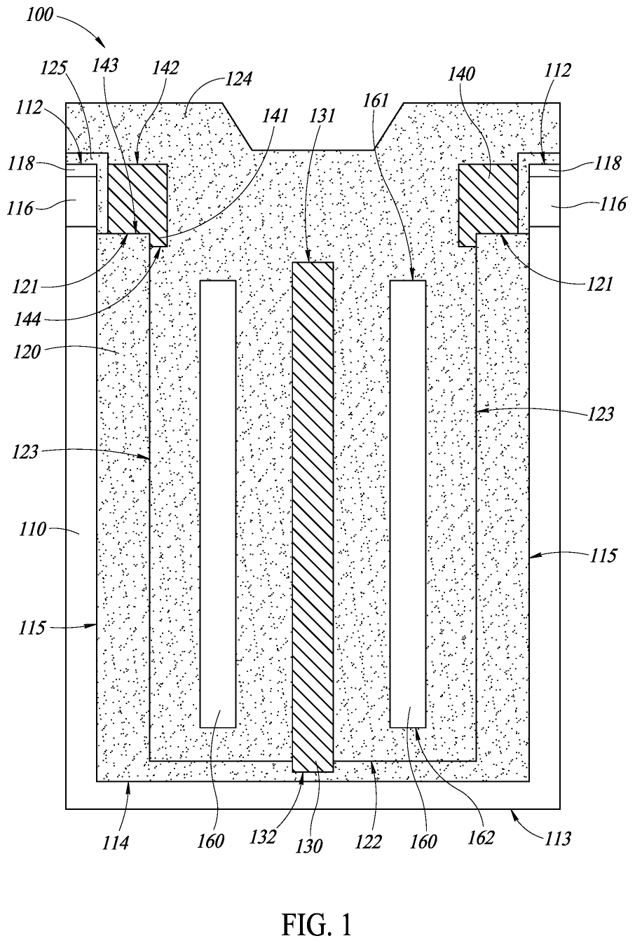

FIG. 1 is a power MOSFET device 100 including a first insulating layer 120 on a recessed substrate 110. The device 100 comprising a second insulating layer 124 on the first insulating layer 120. A polysilicon source 130 is in the second insulating layer 124 and extends in the first insulating layer 120. The second insulating layer 124 has at least one air gap 160 between sidewalls 115 of the recessed substrate 110 and the polysilicon source 130. At least one gate 140 is on the first insulating layer 120. A third insulating layer 125 separates the gate 140 from the recessed substrate 110 having a drain region 116 and a source region 118, the source region 118 being on the drain region 116.

The recessed substrate 110 has a first or top surface 112 opposite a second or bottom surface 113. A recess or trench extends from the first surface 112 in a vertical or first direction. The recess has sidewalls 115 opposite each other extending in the vertical direction to a third surface or bottom of the recess 114. The bottom surface of the recess 114 extending between the sidewalls 115 in a horizontal or second direction transverse the first direction.

The bottom surface of the recess 114 extending in the horizontal direction for a first dimension or width. The sidewall 115 of the recess extends in the first direction for a second dimension. In some embodiments, the first dimension of the bottom surface the recess 114 is less than the second dimension of the sidewall 115.

The recessed substrate 110 is silicon, or other suitable semiconductor material.

The substrate 110 includes the source region 118 on the drain region 116. The source region 118 adjacent to the top surface of the substrate 112.

The first insulating or field plate oxide layer 120 is on the substrate 110 and in the recess. The first insulating layer 120 entirely coats or covers the bottom surface of the recess 114. Sidewalls 115 of the recess are partially covered by the first insulating layer 120. Said differently, a first or top surface the first insulating layer 121 does not extend past the first surface of the substrate 112. The top surface of the first insulating layer 121 is transverse to the sidewalls of the recessed substrate 115.

In some embodiments, the top surface of the first insulating layer 121 is adjacent and below the drain region 116. Said differently, the first insulating layer 120 does not contact the drain region 116.

The first insulating layer 120 includes second or lateral surfaces 123 transverse to the first surface of the first insulating layer 121. The lateral surfaces of the first insulating layer 123 extend to a third or bottom recessed surface of the first insulating layer 122. The bottom surface of the insulating layer 122 is opposite the bottom surface of the recess 114. The bottom surface of the insulating layer 122 extends between the lateral surfaces of the first insulating layer 123.

The insulating layer is silicon dioxide or other suitable insulating material.

In some embodiments, a thickness of the first insulating layer 120 is not uniform throughout. In one embodiment, a thickness of the first insulating layer 120 on the bottom surface of the recessed substrate 114 is less than a thickness of the first insulating layer 120 on the sidewalls 115. In other embodiments, the thickness of the first insulating layer 120 is substantially uniform throughout.

The second insulating layer 124 is on the first insulating layer 120. The second insulating layer 124 is in the recess of the substrate 110 and extends above the recess. The second insulating layer 124 contacts the first, second, and third surfaces 121, 122, 123 of the first insulating layer 120. The second insulating layer 124 extends past the first surface of the substrate 112. The second insulating layer 124 covers the buried polysilicon source 130 and the gates 140. The second insulating layer 124 covers and delimits the air gaps 160.

In some embodiments, the second insulating layer 124 is made of the same material as the first insulating layer 120. In this embodiment, the second insulating layer 124 is silicon dioxide.

In some embodiments, the first insulating layer 120 and the second insulating layer 124 are continuous and integral.

In some embodiments, there is a recess or indentation in the second insulating layer 124 opposite the first end of the polysilicon source 131. In one embodiment, the recess is a central recess. The recess does not extend past a top surface of the gate 142.

The third insulating layer 125 is between the first insulating layer 120 and the second insulating layer 124. The third insulating layer 125 is between the gate 140 and the substrate 110. The third insulating layer 125 covers the top surface of the substrate 112. The third insulating layer 125 extends in the vertical direction on the top surface of the substrate 112 so that a top surface of the third insulating layer 125 is above the top surface of the gate 142. The third insulating layer 125 covers a portion of the sidewalls of the recessed substrate 115. The third insulating layer 125 contacts the drain region 116 and the source region 118.

In this embodiment, the third insulating layer 125 has an “L” or corner shape, meaning a first portion is transverse to a second portion. The third insulating layer 125 covers a corner of the substrate 110. In other embodiments, the third insulating layer 125 has a different shape.

In some embodiments, the third insulating layer 125 is made of the same material as the first insulating layer 120. In this embodiment, the third insulating layer 125 is silicon dioxide.

Buried in the second insulating layer 124 is the polysilicon source or field plate 130. The polysilicon source 130 is centrally located in the recess of the substrate 110. The polysilicon source 130 has a top surface 131 opposite a bottom surface 132. The top surface of the polysilicon source 131 is transverse lateral surfaces. The top surface of the polysilicon source 131 is covered by the second insulating layer 124. The top surface of polysilicon source 131 does not extend past the first surface of the first insulating layer 121.

The bottom surface of the polysilicon source 132 is in the first insulating layer 120. The bottom surface of the polysilicon source 132 is adjacent and opposite the bottom surface of the recess 114. Said differently, the polysilicon source 130 does not extend through the first insulating layer 120 to contact the substrate 110. The first insulating layer 120 contacts portions of the lateral surfaces of the polysilicon source 130 adjacent to the bottom surface of the polysilicon source 132.

The polysilicon source 130 extends in the vertical direction for a first dimension. The polysilicon source 130 extends in the horizontal direction for a second dimension. The second dimension of the polysilicon source 130 is less than the first dimension of the polysilicon source 130.

In some embodiments, the polysilicon source 130 has an elongated shape in the first direction. In other embodiments, the polysilicon source 130 has a different shape.

Spaced from the polysilicon source 130 is the at least one buried air gap or bubble 160. The air gap 160 is in and completely surrounded by the second insulating layer 124. Said differently, the second insulating layer 124 delimits the air gap 160 in the recess of the substrate 110.

The air gap 160 has a first or top end 161 opposite a second or bottom end 162. The first end of the air gap 161 does not extend past the top surface of the first insulating layer 121. The top end of the air gap 161 is adjacent to the top surface of the polysilicon source 131. Whereas the second end of the air gap 162 is adjacent to the bottom surface of the polysilicon source 132. The second end of the air gap 162 is opposite and adjacent to the third surface of the first insulating layer 122.

The air gap 160 extends in the vertical direction for a first dimension. Said differently, the first dimension is between the top and bottom ends 161, 162. The air gap 160 extends in the horizontal direction for a second dimension. The first dimension of the air gap 160 is greater than the second dimension of the air gap 160.

The first dimension of the air gap 160 is less than the first dimension of the polysilicon source 130. The polysilicon source 130 extends past the first and second ends of the air gap 161, 162.

In this embodiment, there are a plurality of air gaps 160 of substantially similar size and shape. Ones of the air gaps 160 is between each respective sidewall of the substrate 115 and the polysilicon source 130. The polysilicon source 130 is spaced substantially equidistant from each of the air gaps 160. The polysilicon source 130 is separated from the air gaps 160 via the second insulating layer 124.

In some embodiments, the air gap 160 is centrally located between the polysilicon source 130 and the first insulating layer 120. In some embodiments, the air gap 160 is centrally located in the first direction between the top surface of the first insulating layer 121 and the bottom surface of the first insulating layer 122.

In some embodiments, the first dimension of the air gap 160 is more than half of the first dimension of the polysilicon source 130.

In some embodiments, the air gap 160 has a size and shape similar to the polysilicon source 130 with a lesser vertical dimension.

In some embodiments, the second dimension of the air gap 160 ranges from 0.1 to 0.3 μm. In one embodiment, the second dimension of the air gap 160 is about 0.2 μm.

The at least one gate 140 is adjacent to the first end of the air gap 161. The gate 140 is on the top surface of the first insulating layer 121. The gate 140 does not extend past the first end of the air gap 161. A top surface of the gate 142 is substantially planar with the first surface of the substrate 112.

The gate 140 does not entirely cover the top surface of the first insulating layer 121. Instead, the third insulating layer 125 separates the gate 140 and the substrate 110. The third insulating layer 125 contacts the top surface of the first insulating layer 121 that is between the substrate 110 and the gate 140. The drain region 118 is opposite the gate 140. The source region 116 is also opposite the gate 140.

The top surface of the gate 142 is recessed from the top surface of the third insulating layer 125. Said differently, the top surface of the gate 142 is transverse to a surface of the third insulating layer 125.

In some embodiments, the top surface of the gate 142 extends past the top surface of the substrate 112. In other embodiments, the top surface of the gate 142 is coplanar with the top surface of the substrate 112. In other embodiments, the top surface of the gate 142 is below or recessed from the top surface of the substrate 112.

A bottom surface of the gate 143 is opposite the top surface of the gate 142. The gate 140 has lateral surfaces transverse to the bottom and top surfaces of the gate 143, 142. The lateral surfaces of the gate 140 are opposite each other. The bottom surface of the gate 143 abuts or contacts the top surface of the first insulating layer 121.

The gate 140 includes a protrusion 141 extending from the bottom surface of the gate 143. The gate protrusion 141 extends on the lateral surface of the first insulating layer 123. The gate protrusion 141 has a bottom surface 144 transverse to the lateral surface of the first insulating layer 123. Said differently, the gate protrusion surface 144 is opposite the top surface of the gate 142. The second insulating layer 124 covers a lateral surface of the gate protrusion 141. The lateral surface of the gate protrusion 141 is transverse to the bottom surface of the gate protrusion 144.

The gate 140 is made of polysilicon or other suitable material. In some embodiments, the gate region is made of the same material as the buried polysilicon region.

In some embodiments, the device 100 includes a plurality of gates 140. Ones of the plurality of gates 140 facing each other and separated by the second insulating layer 124. Ones of the plurality of gates 140 being separated from a respective sidewall of the recessed substrate 115 via the third insulating layer 125.

Drain and source regions 116, 118 are in the substrate 110 at or near the first surface of the substrate 112. The drain and source regions 116, 118 are doped regions including n, p, or combination thereof. The substrate 110 may also include body regions.

In some embodiments, the drain region 116 does not extend past the top surface of the first insulating layer 121.

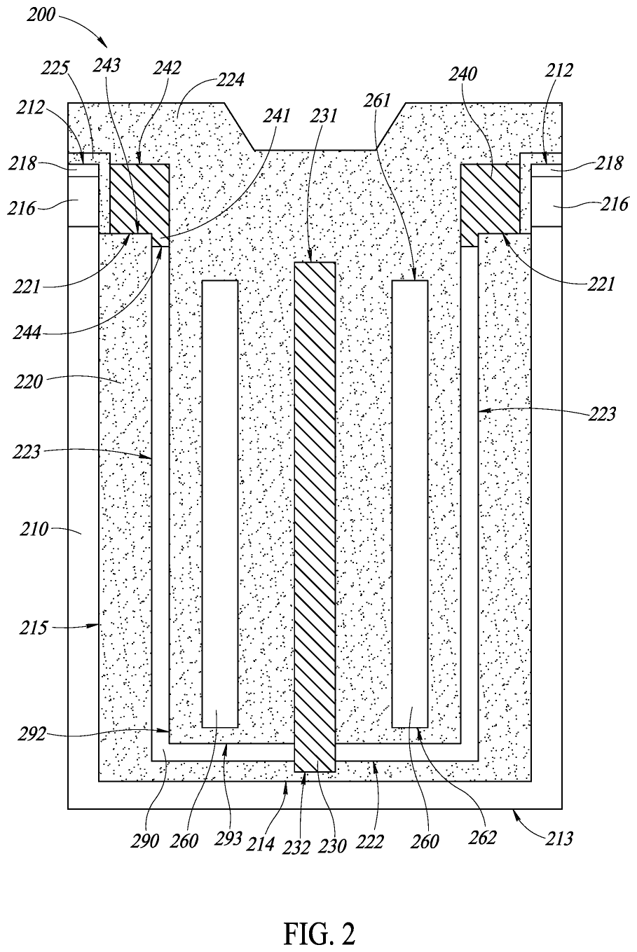

FIG. 2 is a power MOSFET device 200 according to another embodiment. As in FIG. 1, the device 200 includes a first insulating layer 220 on a recessed substrate 210. A nitride layer 290 is on the first insulating layer 220. A second insulating layer 224 is on the nitride layer 290. In the second insulating layer 224 is a buried polysilicon source 230. The device 200 includes at least one air gap 260 between the nitride layer 290 and the buried polysilicon source 230. The device 200 includes drain and source regions 216, 218 in the substrate 210 adjacent to a gate 240. The gate 240 is on the first insulating layer 220 and the nitride layer 290. A third insulating layer 225 separates the gate 240 and the recessed substrate 210.

As in FIG. 1, the substrate 210 has a recess in a first surface 212. The first surface of the substrate 212 is opposite a second surface of the substrate 213. Sidewalls of the substrate 215 extend to a third surface of the substrate 214.

As in FIG. 1, the first insulating layer 220 is the recess of the substrate 210 and entirely covers the bottom surface of the substrate 214. The first insulating layer 220 is on a portion of the sidewalls of the substrate 215. The first insulating layer 220 has a first or top surface 221 transverse to the sidewalls of the substrate 215. A second surface or sidewall of the first insulating layer 223 extends transverse to the first surface of the first insulating layer 221. A third surface of the first insulating layer 222 extends transverse to the second surface of the first insulating layer 223. The third surface of the first insulating layer 222 is opposite the third surface of the substrate 214 and extends between the sidewalls of the substrate 215.

The nitride layer 290 has a top or first surface transverse to the second surface of the first insulating layer 223. The top surface of the nitride layer 290 is in the recess of the substrate 210. The first surface of the nitride layer 290 is recessed from the first surface of the first insulating layer 221.

A second surface or sidewall of the nitride layer 292 extends transverse to the first surface of the nitride layer 290. A third surface of the nitride layer 293 extends transverse to the second surface of the nitride layer 292. The third surface of the nitride layer 293 is opposite the third surface of the first insulating layer 222. Portions of the second surface of the first insulating layer 223 are exposed from the nitride layer 290.

The top surface of the nitride layer 290 contacts or abuts the gate 240. A thickness of the nitride layer 290 is substantially equal to a thickness of the protrusion of the gate 240.

In some embodiments, the nitride layer 290 has a thickness less than a thickness of the first insulating layer 220. In other embodiments, the nitride layer 290 has a thickness substantially equal to a thickness of the first insulating layer 220.

In some embodiments, the nitride layer has a thickness ranging from 0.1 to 0.5 μm. In one embodiment, the nitride layer has thickness of about 0.35 μm.

As in FIG. 1, the gate 240 includes a top surface 242 opposite a bottom surface 243. Lateral surfaces of the gate 240 are transverse to the top and bottom surfaces 242, 243. A protrusion of the gate 241 extends from the bottom surface of the gate 243. The gate protrusion 241 has a bottom surface 244 opposite the top surface of the gate 242.

The bottom surface of the gate protrusion 244 contacts the top surface of the nitride layer 290. The bottom surface of the gate protrusion 244 being transverse to the lateral surface of the first insulating layer 220. The bottom surface of the gate protrusion 244 is adjacent to the top surface of the first insulating layer 221.

As in FIG. 1, the device 200 includes the buried polysilicon source 230. The polysilicon source 230 has a first or top surface 231 opposite a second or bottom surface 232. The top surface of the polysilicon source 231 being completely covered by the second insulating layer 224. The bottom surface of the polysilicon source 232 is adjacent to the third surface of the substrate 214.

The polysilicon source 230 extends through the nitride layer 290. Said differently, portions of the nitride layer 290 contact portions of the polysilicon source 230. The bottom surface of the polysilicon source 232 is in and completely covered by the first insulating layer 220. Said differently, portions of the first insulating layer 220 contact portions of the polysilicon source 230.

In some embodiments, the polysilicon source 230 extends about midway in the first insulating layer 220.

In this embodiment, the polysilicon source 230 separates the nitride layer 290 into two portions, each portion coating a respective sidewall of the recess 215. The two portions of the nitride layer 290 have the substantially same size and shape. In one embodiment, the two portions of the nitride layer 290 are mirror images or reflections of each other.

The third insulating layer 225 has similar features as described in FIG. 1.

As in FIG. 1, the second insulating layer 224 includes the at least one air gap 260. The second insulating layer 224 completely surrounding and delimiting the air gap 260. The air gap 260 is in the recess of the substrate 210 and adjacent to the polysilicon source 230. The air gap 260 has a first end 261 opposite a second end 262. The first end of the air gap 261 does not extend past the top surface of the polysilicon source 231. The first end of the air gap 261 does not extend past the top surface of the nitride layer 290. The first end of the air gap 261 is adjacent to the top surface of the polysilicon source 231. The first end of the air gap 261 is spaced from and adjacent to the bottom surface of the gate protrusion 244.

The air gap 260 is between the second surface of the nitride layer 292 and the polysilicon source 230. The second end of the air gap 262 is spaced from the third surface of the nitride layer 293 via the second insulating layer 224. The second end of the air gap 262 does not contact the nitride layer 290.

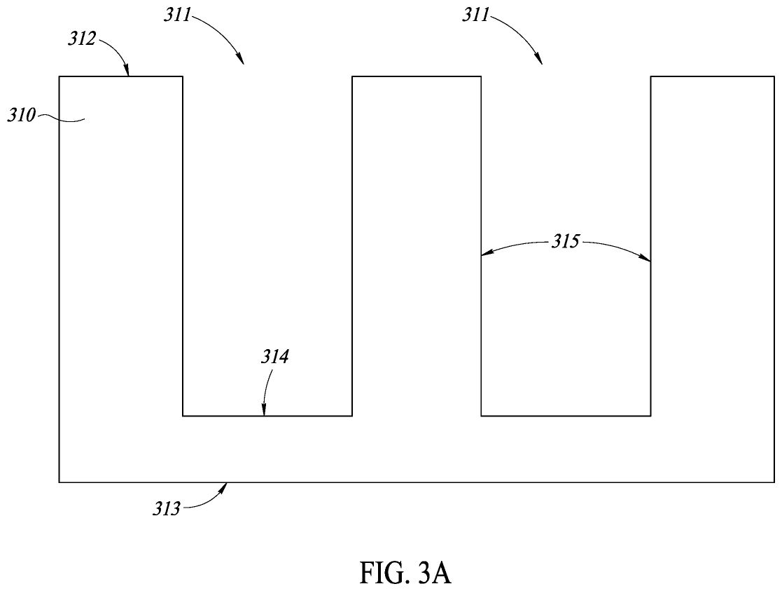

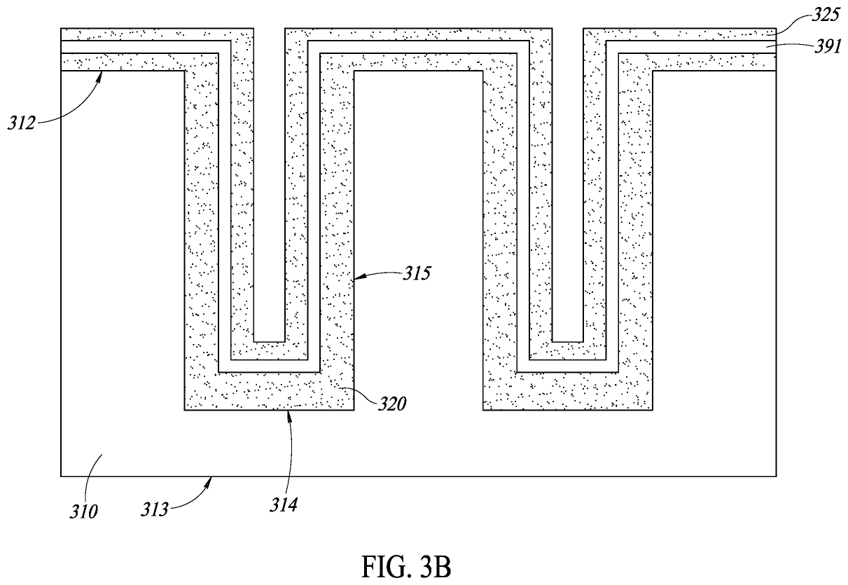

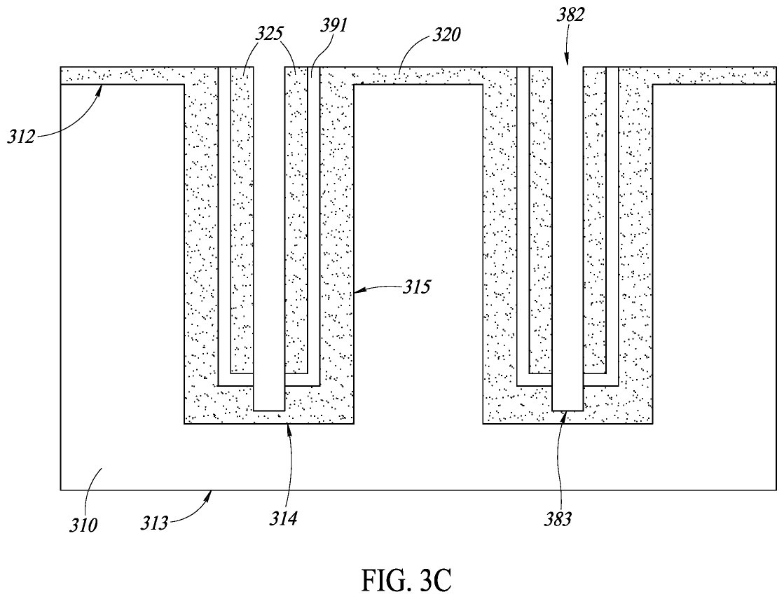

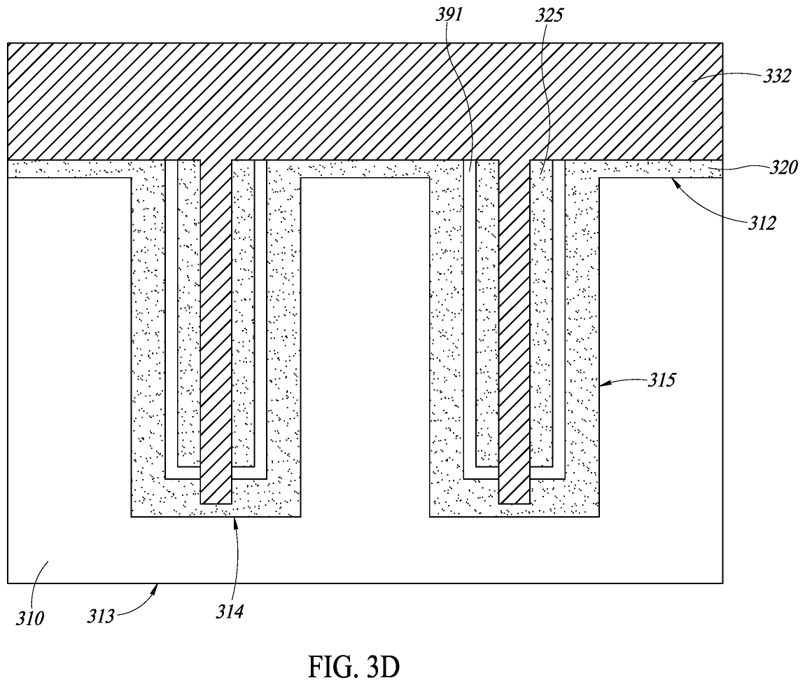

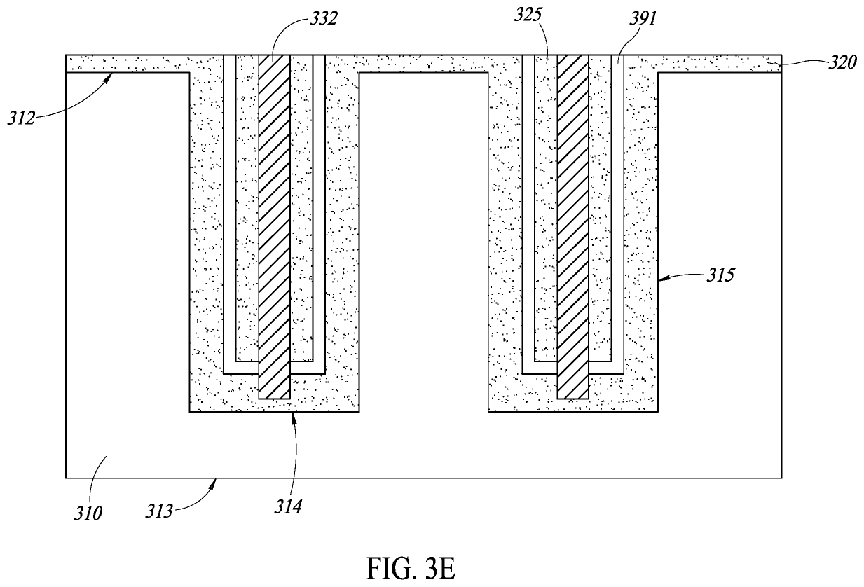

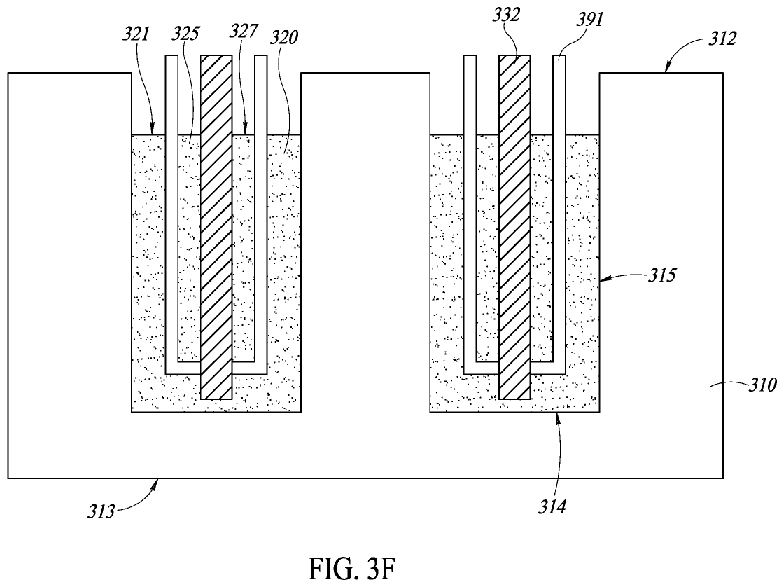

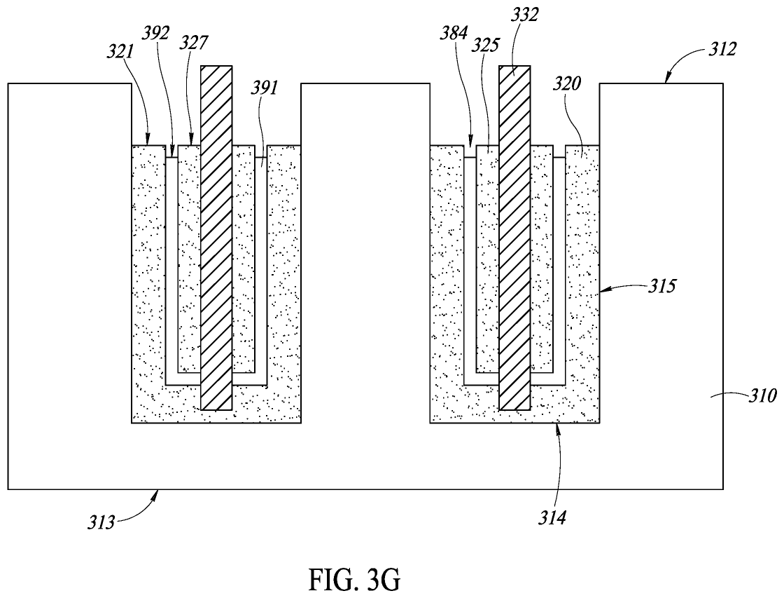

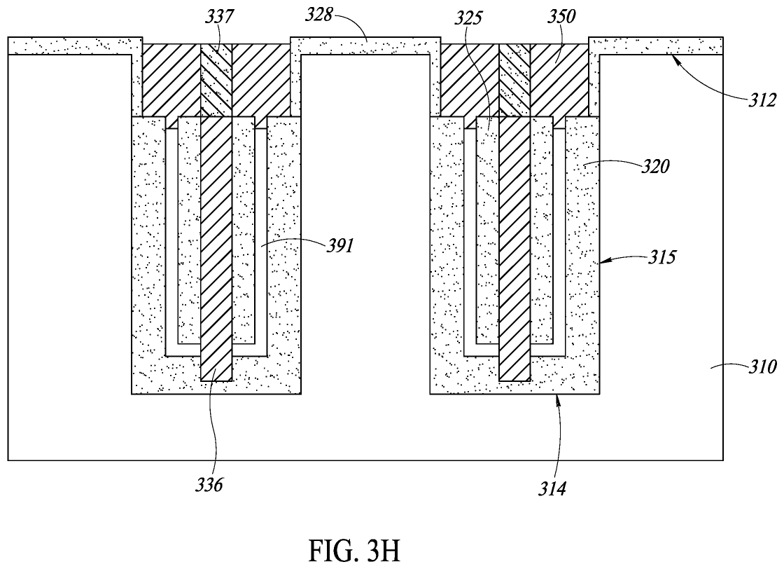

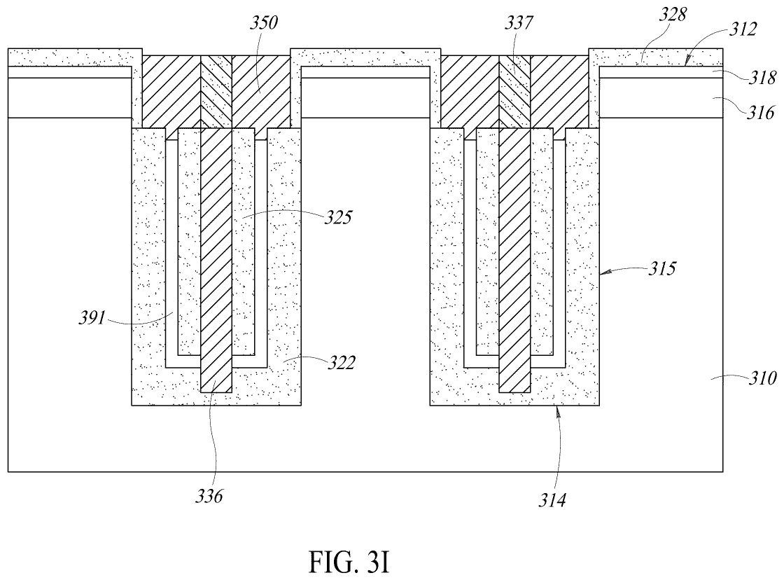

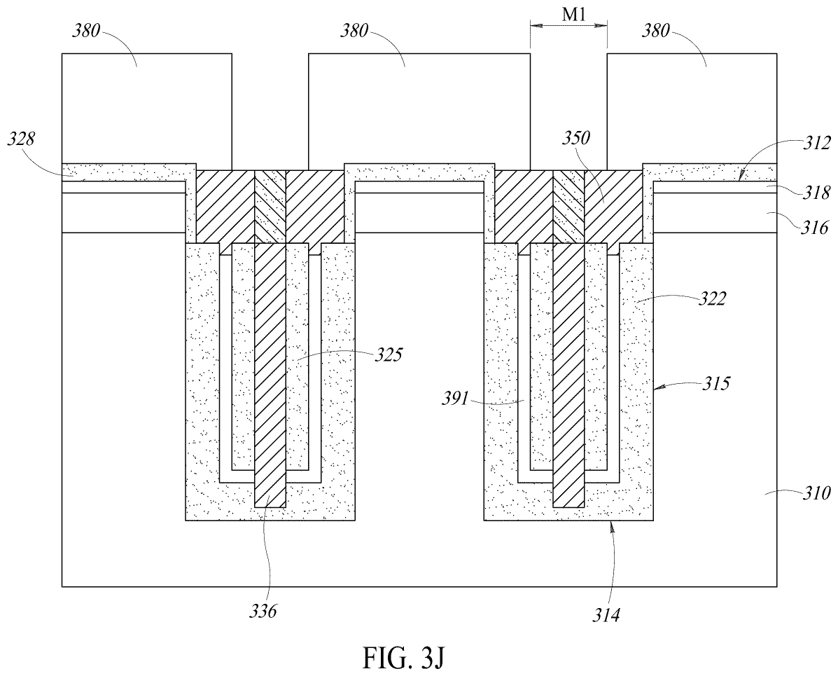

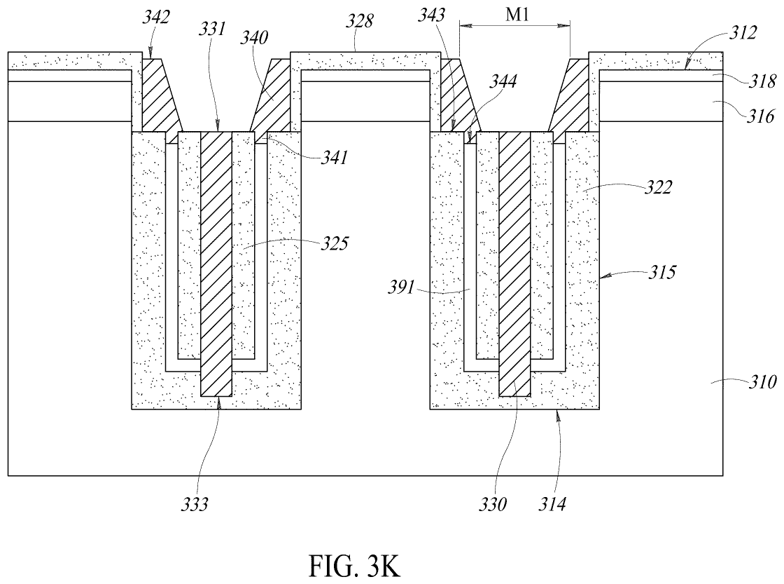

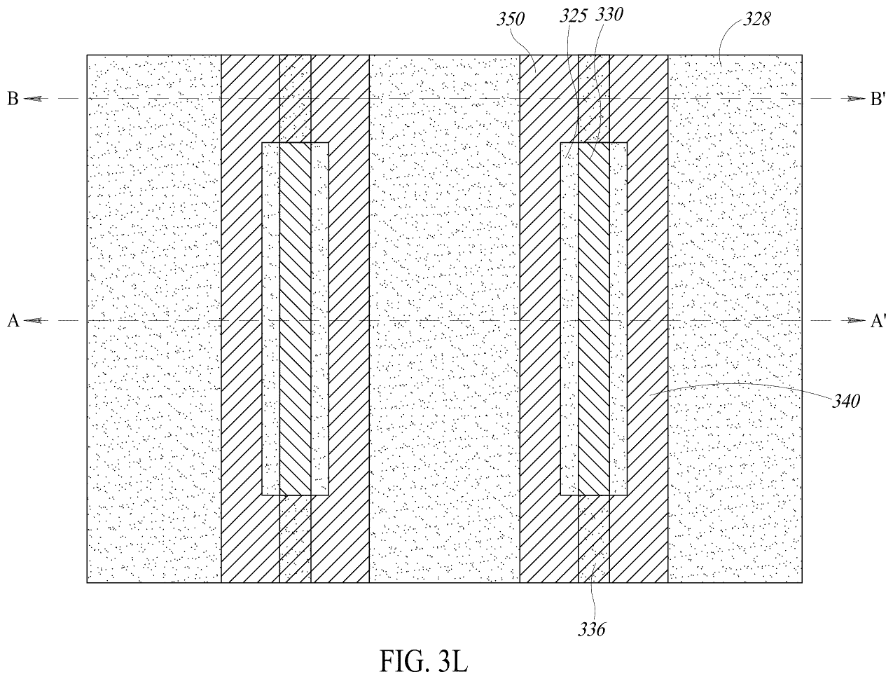

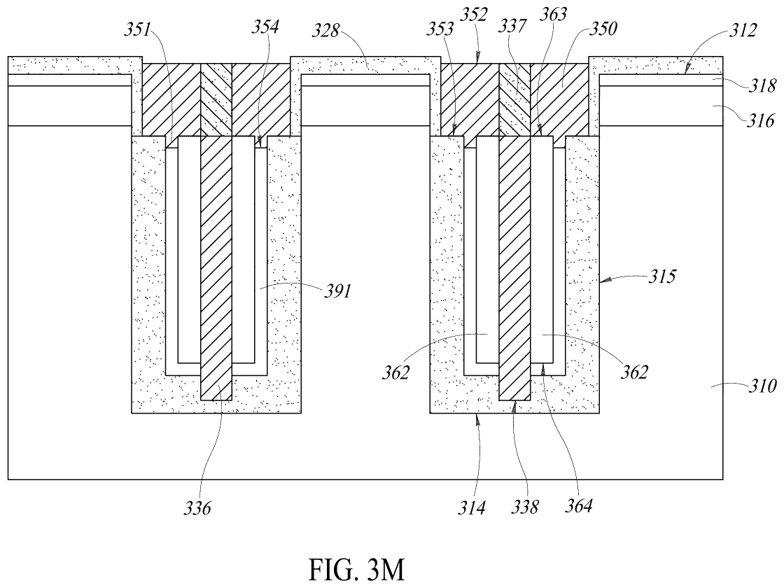

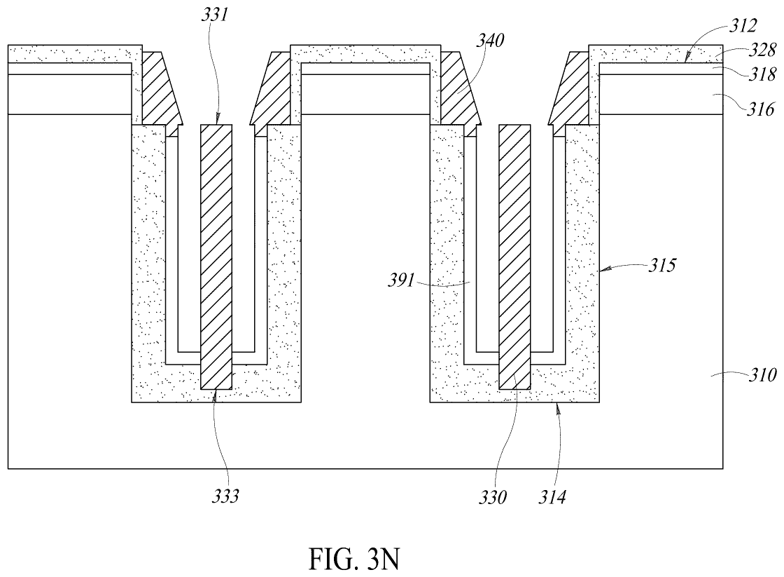

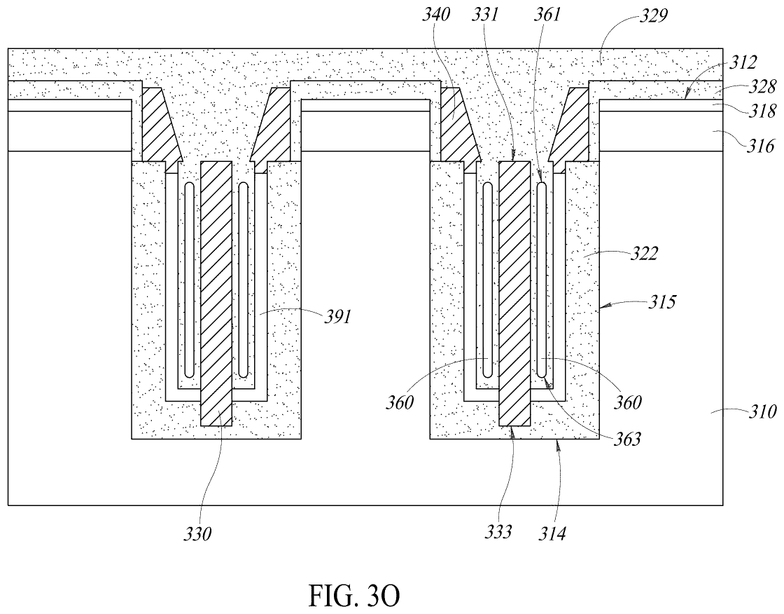

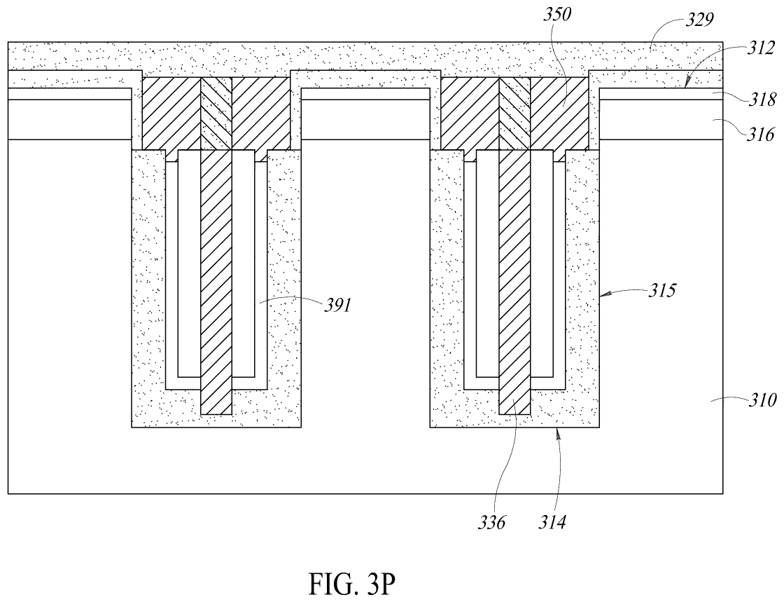

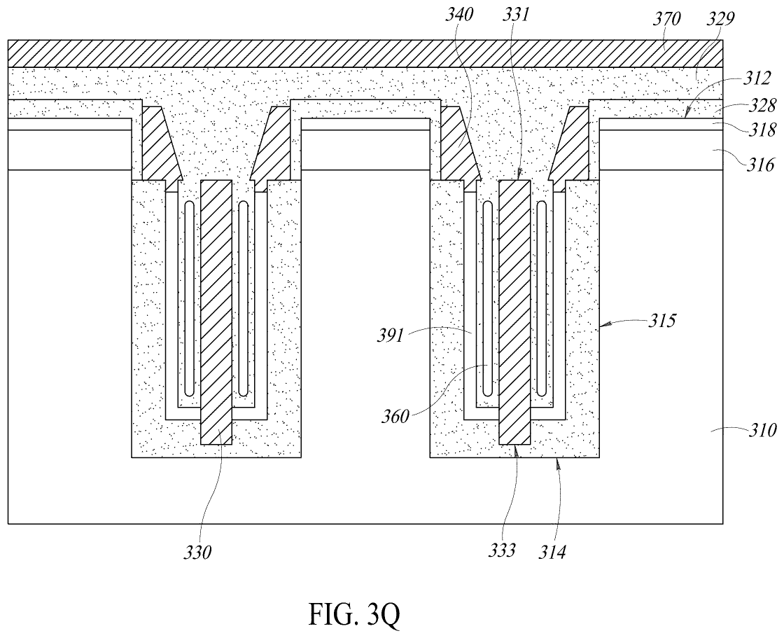

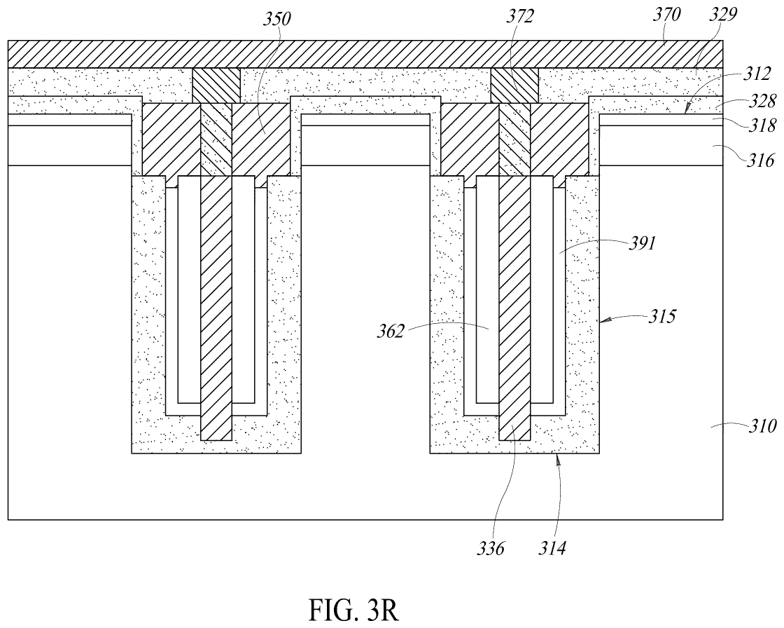

FIGS. 3A-3R are steps of a method of manufacturing the device 200 of FIG. 2. Chemical Vapor Deposition (CVD) can be used to easily coat sidewalls, then pinch off the middle, to form a closed air gap in a single step.

FIG. 3A is a substrate 310 having a first or top surface 312 opposite a second or bottom surface 313. The substrate 310 has a plurality of recesses or trenches 311 of substantially similar size and shape in the first surface of the substrate 312. The recesses 311 are spaced from each other. Each recess has sidewalls 315 extending from the first surface 312 to a respective bottom surface of the recess 314. The bottom surface of the recess 314 is opposite the second surface of the substrate 313. The substrate 310 is silicon or other suitable material.

In one embodiment, the bottom surface of the recess 314 extends in the second direction for a range of 1 to 2 μm. In one embodiment, the bottom surface of the recess 314 extends in the horizontal direction for about 1.6 μm. In some embodiments, the sidewalls of the recess 315 extend in the vertical direction for a range of 4 to 6 μm. In one embodiment, the sidewalls of the recess 315 extend in the vertical direction for about 5 μm.

Next, in FIG. 3B, a first insulating layer 320, a nitride layer 391, and a second insulating layer 325 is formed on the substrate 310 and in the recesses 311. The nitride layer 391 is between the first insulating layer 320 and the second insulating layer 325. The first insulating layer 320 covers the first surface of the substrate 312, the sidewalls 315 and the bottom surfaces of the recesses 314. The first insulating layer 320 has a first thickness. In one embodiment, the first insulating layer 320 has a thickness of 2 kÅ.

The nitride layer 391 has a second thickness less than the first thickness of the first insulating layer 320. The nitride layer 391 covers a top surface of the first insulating layer 320. In one embodiment, the nitride layer 391 has a thickness of 400 Å. The nitride layer 391 is silicon nitride or other suitable material.

The second insulating layer or sacrificial oxide layer 325 has a third thickness less than the first thickness of the first insulating layer 320. The first and second insulating layers 320, 325 may be of the same material. The second insulating layer 325 entirely covers a top surface of the nitride layer 391. In one embodiment, the second insulating layer 325 has a thickness of 4 kÅ. In other embodiments, the second insulating layer 325 has a thickness of 0.35 μm.

Next, in FIG. 3C, portions of the nitride layer 391, first insulating layer 320, and second insulating layer 325 are removed. Recesses 382 are formed that are delimited by the first and second insulating layers 320, 325 and the nitride layer 391. Surfaces of the first and second insulating layers 320, 325 and the nitride layer 391 that delimit the recesses 382 are coplanar. Removal exposes a top surface of the first insulating layer 320, a top surface of the nitride layer 391, and a top surface of the second insulating layer 325. The top surfaces of the first insulating layer 320, nitride layer 391, and second insulating layer 325 being coplanar. A bottom surface of the recess 383 is delimited by the first insulating layer 320. The bottom surface of the recess 383 is opposite the bottom surface of the substrate recess 314.

In some embodiments, the removal is carried out via nitride dry etch.

In some embodiments, the removal is carried out via etching in the vertical direction.

Next, in FIG. 3D, a polysilicon material 332 is deposited on the substrate 310. The polysilicon material 332 entirely fills the recesses 382. The polysilicon material 332 covers the top surfaces of the first and second insulating layer 320, 325 and the top surfaces of the nitride layer 391.

Next, in FIG. 3E, portions of the deposited polysilicon material 332 are removed. A top surface of the polysilicon material 332 is exposed and is coplanar with the top surfaces of the first and second insulating layers 320, 325 and the nitride layer 391.

In some embodiments, the polysilicon material 332 extends past the first surface of the substrate 312. In other embodiments, the polysilicon material 332 does not extend past the first surface of the substrate 312. Said differently, the top surface of the polysilicon material 332 is coplanar with the first surface of the substrate 312.

In some embodiments, the removal is carried out via chemical mechanical planarization or polishing.

Next, portions of the first and second insulating layers 320, 325 are removed in FIG. 3F. The removal is carried out at the top surfaces of the first and second insulating layers 320, 325 and exposes a plurality of recessed top surfaces of the first and second insulating layers 321, 327. The recessed top surfaces 321, 327 being recessed from the first surface of the substrate 312. The polysilicon material 332 and the nitride layer 391 extend past the recessed top surfaces 321, 327. Top surfaces of the polysilicon material 332 and the nitride layers 391 are coplanar. The polysilicon material 332 and the nitride layers 391 extend past the top surface of the substrate 312.

In other embodiments, the polysilicon material 332 and the nitride layers 391 do not extend past the top surface of the substrate 312.

In some embodiments, the removal is carried out via wet etch.

Next, in FIG. 3G, portions of the nitride layers 391 are removed. The removed portions are from the top surface of the nitride layer 391 and exposes recessed top surfaces of the nitride layers 392. Removal forms a plurality of recesses 384 delimited by the top surfaces of the nitride layers 392 and lateral surfaces of the first and second insulating layers 320, 325. The recessed top surfaces of the nitride layers 392 being recessed from the top surfaces of the first and second insulating layers 321, 327. The recesses 384 being between the first and second insulating layers 321, 327.

In some embodiments, the removal is carried out via wet etch.

Next, in FIG. 3H, a third insulating layer 328 is formed on the substrate 310. The third insulating layer 328 covers the top surface of the substrate 312 and extends along sidewalls of the substrate 315. The third insulating layer 328 contacts top surfaces of the first insulating layer 320. An exposed portion of the polysilicon material 332 is oxidized. The oxidized portion 337 extends past the top surfaces of the second insulating layer 325. Thereby forming a polysilicon source 336 including an oxidized upper portion 337.

A second polysilicon material is deposited on the first and insulating layers 320, 325. The second polysilicon material fills the recesses 384 and contacts the recessed top surfaces of the nitride layers 392. Top and lateral surfaces of the first and second insulating layers 320, 325 contact the second polysilicon material. The second polysilicon material contacts the first polysilicon source 336 and the third insulating layer 328.

The gates 350 are formed by removing portions of the second polysilicon material are. Removal exposes a top surface of the gates 350 that are coplanar with a top surface of the oxidized portion of the polysilicon source 337. The top surface of the gates 350 being recessed from the third insulating layer 328. Said differently, the third insulating layer 328 extends past the top surface of the gates 350. The gates 350 include a protrusion that contacts the nitride layer 391.

In some embodiments, the removal is carried out by etching, chemical mechanical planarization, or a combination of both.

Next, in FIG. 3I, source and drain regions 318, 316 are formed in the substrate 310. In some embodiments, forming is carried out via implantation or doping. In some embodiments, forming the source and drain regions 318, 316 is carried out through the third insulating layer 328.

Next, in FIG. 3J, a mask 380 is formed on the substrate 310. The mask 380 is formed in a manner to have a plurality of openings. The openings being on the first polysilicon source 336 so that portions of the gates 350 are exposed from the mask 380. The opening has a dimension M1 in the second direction between portions of the mask 380. In one embodiment, the dimension M1 is 1.2 μm.

Next, in FIG. 3K, the sloped gates 340 are formed in a first portion of the device 200. Forming is carried out by etching the first polysilicon source 336 and the gates 350. The mask 380 is used to pattern the gates 350. The sloped gates 340 have a top surface 342 transverse to a lateral surface of the third insulating layer 328. Exposed sloped surfaces extend from the top surface of the sloped gates 342 to the second insulating layer 325. A bottom surface of the sloped gate 343 is opposite the top surface 342. A protrusion of the sloped gate 341 extends from the bottom surface 343. The protrusion of the sloped gate 341 has a bottom surface 344 that contacts the nitride layer 391.

Etching the first polysilicon source 336 thereby forms the second polysilicon source 330. The second polysilicon source 330 has a top surface 331 coplanar with top surfaces of the second insulating layers 325. A bottom surface of the second polysilicon source 333 is opposite the top surface 331. The bottom surface 333 being in the first insulating layer 322.

In some embodiments, forming is carried out via photolithography. In this embodiment, a photoresist layer is used to pattern the gates 350. After etching, the photoresist layer is removed.

In some embodiments, the second insulating layer 325 has a thickness in the second direction of 0.4 μm. The second polysilicon source 330 has a thickness in the second direction of 0.3 μm. The dimension in the second direction between the polysilicon source 330 and the substrate 310 is 0.6 μm. Said differently, the thickness of the nitride layer 391 and first and second insulating layers 322, 325 is 0.6 μm. The first insulating layer 322 in the second direction has a thickness of 0.2 μm.

FIG. 3L is a top view of the device 200. Cross-section line A-A′ is through the first portion of the device 200 having the sloped gates 340. Whereas cross-section line B-B′ is through a second portion of the device having the gates 350.

FIG. 3M is a cross-section of line A-A′ of FIG. 3L and FIG. 3N is a cross-section of line B-B′ of FIG. 3L. Next, the second insulating layers 325 are removed. In some embodiments, the removal is carried out via wet etch.

In FIG. 3M, air gaps 362 are formed by the removal. The air gaps 362 are buried below the gates 350. The air gaps 362 are delimited by the gates 350, including the gate protrusions 351, the nitride layer 391, and the polysilicon source 336. A top surface of the gates 352 is opposite a bottom surface of the gates 353. Portions of the bottom surfaces of the gates 353 that are between the polysilicon source 336 and the protrusions delimit the air gaps 362.

In FIG. 3N, the removal exposes lateral surfaces of the polysilicon source 333 and surfaces of the nitride layer 391. Surfaces of the sloped gates 340 are also exposed, including surfaces of the gate protrusions.

Next, a fourth insulating layer 329 is formed. In FIG. 3O, a buried air gap 360 is formed. The air gap 360 is buried in the fourth insulating layer 329. The air gap has a first end 361 opposite a second end 363. The first end of the air gap 361 does not extend past the top surface of the top surface of the first insulating layer.

In some embodiments, the air gap 360 is formed via non-conformal chemical vapor deposition of oxide.

In FIG. 3P, the fourth insulating layer 329 is formed on the first surface of the substrate 312 covering the top surface of the gate 340 and third insulating layer 328.

Next, a conductive layer 370 is formed on the insulating layer 329. In FIG. 3Q and FIG. 3R, the conductive layer 370 is formed entirely on the insulating layer 329.

In some embodiments, the conductive layer 370 is aluminum or other suitable material. In some embodiments, the conductive layer 370 is formed via plasma metal deposition and planarization.

In FIG. 3R, a step of metallization is carried out. In this embodiment, the metallization includes forming contacts 372. The contacts 372 are between the conductive layer 370 and the gate 350. The contacts 372 contact the buried polysilicon source 336.

In some embodiments, the contacts 372 are made of tungsten or other suitable conductive material.

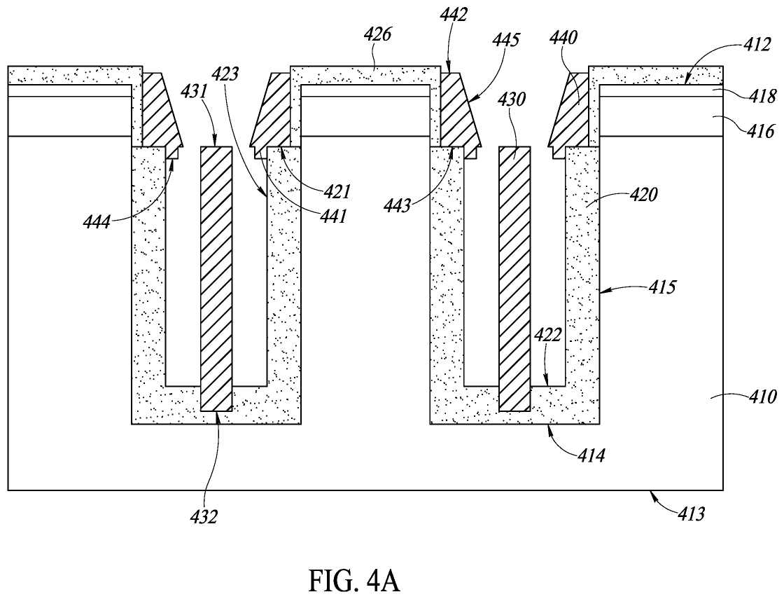

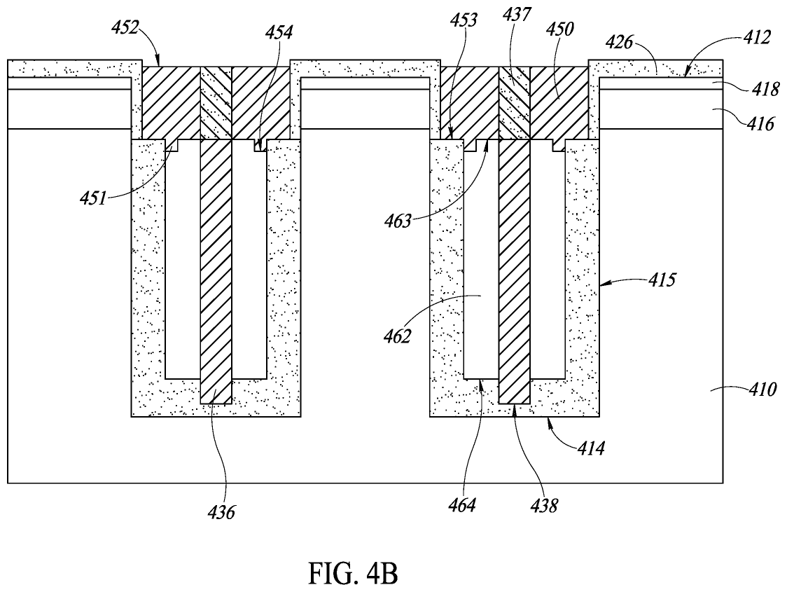

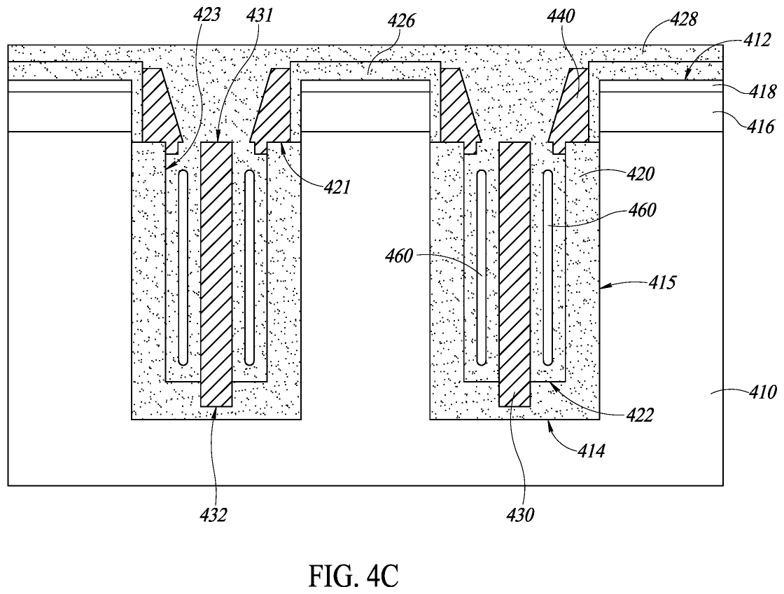

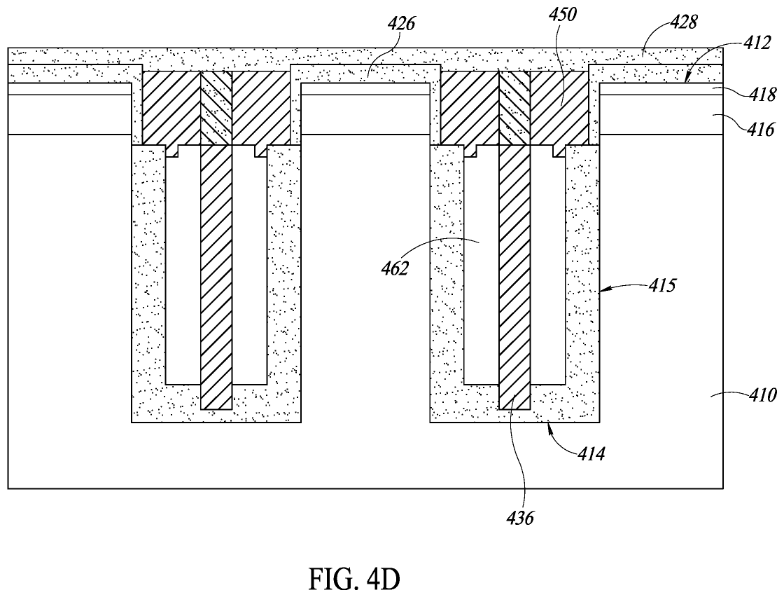

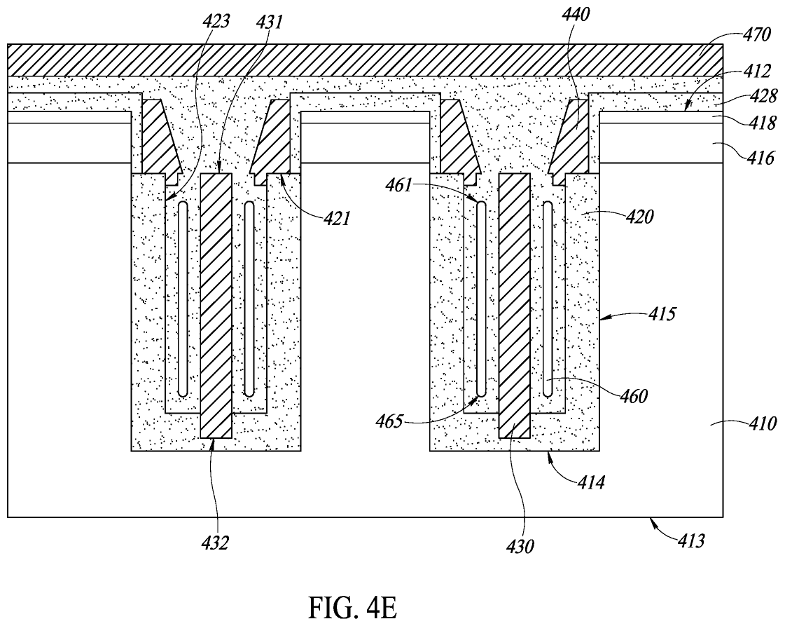

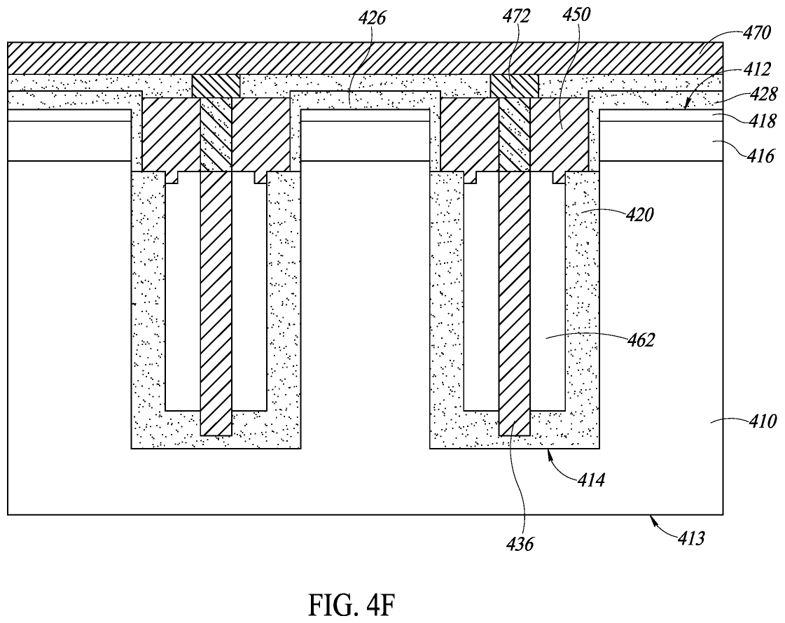

FIGS. 4A-4F are steps of a method of manufacturing the device 100 of FIG. 1. Prior to FIGS. 4A and 4B, similar steps as those described for FIGS. 3A-3L are carried out.

Not shown, a substrate 410 has a plurality of recesses in a first surface of the substrate 412, as in FIG. 3A. A second surface of the substrate 413 is opposite the first surface 412.

Next, not shown, a first insulating layer 420, a nitride layer, and a second insulating layer is formed on the substrate 410, as in FIG. 3B.

Next, not shown, the first insulating layer 420, the nitride layer, and the second insulating layer is etched, as in FIG. 3C, to form a recess.

Next, not shown, a polysilicon material is deposited, as in FIG. 3D. The polysilicon material filling the recess.

Next, not shown, a step of planarization is carried out thereby making top surfaces of the first insulating layer 420, the nitride layer, the second insulating layer, the polysilicon material, and the substrate 410 coplanar, as in FIG. 3E.

Next, not shown, the first insulating layer 420 and the second insulating layer is etched, as in FIG. 3F. Top surfaces of the first insulating layer 420 and the second insulating layer are recessed from the top surface of the polysilicon material.

Next, not shown, a third insulating layer 426 is formed on the substrate 410, as in FIG. 3H. A portion of the polysilicon material that is exposed is oxidized.

Next, not shown, source and drain regions 418, 416 are formed in the substrate 410, as in FIG. 3I. Forming may be done via doping.

Next, not shown, a mask is formed on the substrate 410, as in FIG. 3J.

Next, not shown, the gates 440 are formed, as in FIG. 3K.

Next, in FIGS. 4A and 4B, the nitride layer and second insulating layer are removed. The nitride layer is also removed in the same manner as the second insulating layer is removed. FIG. 4A is a cross-section from line A-A′ and FIG. 4B is a cross-section from line B-B′, as in FIG. 3L. FIG. 4A is of a portion of the device 200 having the sloped gates 440 and FIG. 4B is a portion of the device 200 having the non-etched gates 450.

In FIG. 4A, the second insulating layer is removed, as in FIG. 3N. Removing exposes surfaces of the polysilicon source 430. Surfaces of the gates 440 are also exposed. Surfaces of the first insulating layer 422, 423 are also exposed. A recessed surface of the first insulating layer 422 being opposite the recessed surface of the substrate 414. Lateral surfaces of the first insulating layer 423 delimit an opening between the polysilicon source 430 and the first insulating layer 423.

In FIG. 4B, the second insulating layer is removed, as in FIG. 3M. Thereby forming buried air gaps 462. The air gaps 462 being between the first insulating layer and the polysilicon source 436. The air gaps 462 being between the gates 450 and the first insulating layer. Said differently, the polysilicon source 436, the first insulating layer, and the gates 450 delimit the air gaps 462.

Next, a fourth insulating layer 428 is formed in FIGS. 4C and 4D.

In FIG. 4C, the fourth insulating layer 428 fills the opening between the polysilicon source 430 and the first insulating layer 423. The fourth insulating layer 428 covers the third insulating layer 426 and the gates 440. Forming the fourth insulating layer 428 forms the buried air gaps 460 in the opening. The fourth insulating layer 428 contacts the recessed surface of the first insulating layer 422. The first, third, and fourth insulating layers 420, 426, 428 may be integral and continuous.

In some embodiments, the air gaps 460 are formed via non-conformal deposition of the fourth insulating layer 428.

In FIG. 4D, the fourth insulating layer 428 is on the gates 450 and the third insulating layer 426. The fourth insulating layer 428 contacts a top surface of the polysilicon source 326.

Next, a conductive layer 470 is formed on the fourth insulating layer 428 in FIGS. 4E and 4F.

In FIG. 4E, the conductive layer 470 entirely covers the fourth insulating layer 428, as in FIG. 3Q.

In FIG. 4F, contacts 472 are formed between the conductive layer 470 and the gates 450, as in FIG. 3R.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a power MOSFET, including:
a substrate, including:
a recess in a first surface of the substrate, the first surface extending in a first direction, the recess having sidewalls extending in a second direction transverse the first direction, the recess including a second surface extending in the first direction between the sidewalls;
an insulating layer on the first surface of the substrate and in the recess;
a first polysilicon region in the insulating layer, the first polysilicon region extending in the second direction for a first dimension; and
an air gap in the insulating layer between the first polysilicon region and the substrate, the air gap extending in the second direction for a second dimension being less than the first dimension.

2. The device of claim 1, wherein the air gap extends in the first direction for a third dimension being less than the second dimension.

3. The device of claim 1, wherein the first polysilicon region extends in the first direction for a third dimension being less than the first dimension.

4. The device of claim 1, wherein first polysilicon region has a first end spaced from the second surface of the recess for a third dimension.

5. The device of claim 4, wherein the air gap has a first end spaced from the second surface of the recess for a fourth dimension, the third dimension being less than the fourth dimension.

6. The device of claim 1, comprising a field plate oxide layer in the recess and between the substrate and the insulating layer, the field plate oxide layer having a first surface extending in the first direction adjacent the first surface of the substrate.

7. The device of claim 6, wherein the first polysilicon region extends in the field plate oxide layer.

8. The device of claim 6, comprising a gate polysilicon region on the first surface of field plate oxide layer, the gate polysilicon region including a protrusion extending into the insulating layer.

9. The device of claim 8, comprising a source region and a body region, the source region being on the body region, the body region contacting the first surface of the substrate, a portion of the insulating layer between the gate polysilicon region and the source and body regions.

10. The device of claim 7, comprising a nitride layer between the field player oxide layer and the insulating layer, the first polysilicon region extending through the nitride layer.

11. The device of claim 1, wherein the air gap is surrounded by the insulating layer.

12. A device, comprising:
a power MOSFET including:
a recessed substrate;
an insulating layer on the recessed substrate;
a first polysilicon region in the insulating layer;
a first air gap in the insulating layer; and
a second air gap in the insulating layer, the first polysilicon region between the first and second air gaps.

13. The device of claim 12, wherein the first and second air gaps are each equally spaced from the first polysilicon region in a first direction.

14. The device of claim 12, wherein the first and second air gaps have substantially the same shape and dimensions.

15. The device of claim 13, wherein the first and second air gaps extend in a second direction transverse the first direction for a first dimension, the first polysilicon region extends in the second direction for a second dimension greater than the first dimension, the first polysilicon region extending through the insulating layer.

16. A method, comprising:
forming a power MOSFET device by:
forming a first insulating layer on a substrate including a recess, the first insulating layer covering a first surface of the substrate, recess sidewalls, and a second surface of the recess extending between the sidewalls;
forming a first polysilicon region in the insulating layer; and
forming an air gap in the insulating layer on the substrate.

17. The method of claim 16, wherein forming the first polysilicon region includes depositing a first polysilicon material on the first insulating layer and in the recess.

18. The method of claim 17, wherein forming the air gap includes etching the insulating layer to expose a surface of the insulating layer that is recessed from the first surface of the substrate.

19. The method of claim 18, comprising forming a gate region by depositing a second polysilicon material on the insulating layer and etching the second polysilicon material.

20. The method of claim 16, comprising forming source and drain regions on the substrate.
